(19) United States
(12) Patent Application Publication
(10) Pub. No.: US 2016/0149566 A1
(43) Pub. Date: May 26, 2016

(54) Devices, Methods and Computer Readable Storage Media Storing Instructions for Generating Pulse Signals

(71) Applicant: EMORY UNIVERSITY, Atlanta, GA (US)

(72) Inventors: Li Sun, Atlanta, GA (US); Josh J. Savory, Louisville, CO (US); Kurt Wamcke, Atlanta, GA (US)

(73) Assignee: Emory University, Atlanta, GA (US)

(21) Appl. No.: 14/901,404

(22) PCT Filed: Jun. 26, 2014
(86) PCT No.: PCT/US2014/044269

§ 371 Date: Dec. 28, 2015

Related U.S. Application Data
(60) Provisional application No. 61/839,998, filed on Jun. 27, 2013.

(30) Foreign Application Priority Data
Jun. 27, 2013 (US) 61839998

(51) Int. Cl. H03K 5/1534; G06F 1/26; G06F 1/04; H03K 5/156

(52) U.S. Cl. CPC H03K 5/1534; H03K 5/1565; G06F 1/266; G06F 1/04

(57) ABSTRACT

Devices, methods, and computer-readable storage media relate to generating a voltage according to a bit pattern. The device may include a memory storing a plurality of bit patterns. Each bit pattern may include at least one set of bits representing a transition time, at least one set of transition bits including a voltage state for each channel for the transition time, and a set of non-transition bits including a voltage state for each channel for a counter value that is different from the transition time. The method may include a pulse control module configured to cause an output of a voltage from each channel corresponding to the voltage state. By storing the transition times and the associated bits instead of the full waveform pattern, full advantage of the speed of the device can achieved while the amount of data to be stored can be minimized.

### CROSS REFERENCE TO RELATED APPLICATION

This application claims priority to Provisional Application Ser. No. 61/839,998 filed Jun. 27, 2013, which is hereby incorporated by reference in its entirety.

### GOVERNMENT ACKNOWLEDGEMENT

This invention was made with government support under Grant DK054514 awarded by the National Institutes of Health. The Government has certain rights in the invention

### BACKGROUND

In many magnetic resonance or photonic experiments, instruments have to be synchronized and controlled by a central device, for example, a pulse generator that can control timing-control pulses for signaling or switching.

Several types of pulse generator have been previously implemented. The first type is based on commercial digital delay generators. For example, a pulse generator for microwave switches has been implemented with five Stanford Research Systems DG535 digital delay generators. See, e.g., Shane, J. et al. A versatile pulsed X•band ENDOR spectrometer. Review of Scientific Instruments. 69(9):3357-3364 (September 1998). The digital delay generators usually have precise control of delay time up to picoseconds, and long delay durations up to thousands of seconds. The disadvantages of using digital delay generators are generally that the total number of pulses is determined by the total number of outputs on all devices, and additional circuitries are needed to combine pulse outputs. The delay generators also usually have small number of output channels and therefore can limit the complexity of the pulse patterns one could have.

The second type of pulse generator is based on the logic pattern/word generator or arbitrary waveform generator (AWG). Although the logic pattern generator/AWG approach allows extensive control over the pulsed patterns, it has several disadvantages for pulsed magnetic resonance experiments. The logic pattern generator/AWG are intended for testing and verification of digital designs with the output patterns of each clock cycle pre-calculated and stored in the finite memories. The maximum pulse pattern durations are therefore limited by the memory size. In addition, programming the pulse pattern into the memory requires substantial setup time. For example, for the Tektronix HFS9003 system, the longest pulse pattern duration is limited to 128 μs with 2 ns time base and 64 Kbits memory, and the GPIB-based PC interface requires several seconds for setting up a simple pulse pattern.

Another approach is a customized application-specific integrated circuit (ASIC) chip that was designed specifically for the purpose of pulsed-electron paramagnetic resonance (EPR) experiments. See, e.g., Gromov, I. et al. Pulse programmer for electron paramagnetic resonance spectroscopy. Concepts in Magnetic Resonance Part B: Magnetic Resonance Engineering. 21B(1): 1-10 (2004). 2 ns resolution and 8 channels per chip, and a simple serial communication protocol were achieved. However, certain essential disadvantages of ASIC technology can greatly limit its universal availability. Most importantly, the ASIC is generally inflexible and difficult to adjust, and the entry barrier for ASIC design and fabrication is generally high. Additionally, ASIC chips generally require additional circuitry to function as stand-alone devices.

### SUMMARY

Thus, there is a need for a pulse generating device configured to controllably generate pulses having design flexibility (e.g., an increased number of transistors per logic element and attendant low energy efficiency), (time) efficiency, and low cost.

This disclosure generally relates to methods, devices, and computer readable storage media that generate a pulse according to stored bit patterns.

In some embodiments, the device may include a memory storing a plurality of bit patterns associated with transition times. The plurality of bit patterns may correspond to a pulse pattern. Each bit pattern may include: at least one set of bits representing a transition time; at least one set of transition bits including a voltage state for each channel for a counter value that corresponds to the transition time; and a set of non-transition bits including a voltage state for each channel for a counter value (or time) that is different from the transition time. The device may also include a pulse control module configured to cause an output of a voltage from each channel corresponding to a voltage state for each respective channel provided in the set of non-transition bits when a counter value is different from the transition time; and a voltage from each channel corresponding to a voltage state for each respective channel provided in the set of transition bits when a counter value is the transition time.

In some embodiments, the device may include an output module configured to output a voltage from each channel to an external device. In some embodiments, the output module may have a serialization factor. The output module may be configured to fix a voltage associated with a voltage state. In some embodiments, the number of sets of non-transition and transition bits may correspond to the serialization factor. In some embodiments, the output module may be configured with a number of channels. In some embodiments, the number may correspond to about two-sixteen channels.

In some embodiments, the set of non-transition bits and the set of transition bits may include a first voltage state and a second voltage state. In some embodiments, the first voltage state may be lower than the second voltage state.

In some embodiments, the device may include a command module configured to access a number of bit patterns. In some embodiments, the number of bit patterns may correspond to a number of transitions. In some embodiments, the command module may be configured to access each bit pattern individually and/or sequentially. In some embodiments, the command module may be configured to access each bit pattern based on at least one of a position in the memory or a transition time. In some embodiments, the position of a bit pattern may correlate with a respective transition time. In some embodiments, the control module may be configured to transfer each bit pattern sequentially and/or individually.

In some embodiments, the device may further include a digital clock manager configured to generate clock signals. In some embodiments, the digital clock manager may be configured to generate at least a first clock, a second clock and a third clock, the second clock corresponding to a main operation clock and the third clock corresponding to an output clock. In some embodiments, the second clock may correspond to about 250 MHz and the third clock may correspond to about 500 MHz.

In some embodiments, the disclosure relates to a method of generating a pulse according to a bit pattern. The method may include monitoring a counter value. The method may include storing a plurality of bit patterns, each bit pattern associated with a transition time. The plurality of bit patterns may correspond to a pulse pattern. In some embodiments, at least one set of bits representing a transition time; at least one set of transition bits including a voltage state for each channel for a counter value that corresponds to the transition time; and a set of non-transition bits including a voltage state for each channel for a counter value (or time) that is different from the transition time. The method may further include causing an output of a voltage from each channel corresponding to a voltage state for each respective channel provided in the set of non-transition bits when a counter value is different from the transition time. The method may be performed by a system having a processor and a memory.

In some embodiments, the method may further include outputting a voltage according the voltage state to an external device.

In some embodiments, the number of sets of transition and non-transition bits may correspond to a serialization factor. In some embodiments, the set of non-transition bits and the set of transition bits each include a first voltage state and a second voltage state. In some embodiments, the first voltage state may be lower than the second voltage state.

In some embodiments, the method may include accessing a number of bit patterns from the buffer or memory. In some embodiments, the number of bit patterns may correspond to a number of transitions. In some embodiments, the accessing may include accessing each bit pattern individually from the buffer after a transition time. In some embodiments, the method may include updating the bit pattern based on the transition. In some embodiments, the command module may be configured to buffer each bit pattern based on at least one of a position in the memory or a transition time. In some embodiments, the position of a bit pattern may correlate with a respective transition time. In some embodiments, the method may further include detecting a trigger; and generating clock signals from an external oscillator. In some embodiments, the method may further include generating at least a first clock, a second clock and a third clock, the second clock corresponding to a main operation clock and the third clock corresponding to an output clock. The second clock may correspond to about 250 MHz and the third clock may correspond to about 500 MHz.

In some embodiments, disclosure may relate to a computer-readable medium. The computer readable medium may store computer-executable instructions for generating a pulse. The instructions may include monitoring a counter value. The instructions may include storing a plurality of bit patterns, each bit pattern associated with a transition time. In some embodiments, each bit pattern may include at least one set of bits representing a transition time, and at least one set of transition bits including a voltage state for each channel for a counter value that corresponds to the transition time, and at least one set of non-transition bits including a voltage state for each channel for a counter value that is different from the transition time for each channel. The instructions may further include causing an output of a voltage from each channel corresponding to a voltage state for each respective channel provided in the set of non-transition bits when a counter value is different from the transition time. In some embodiments, the plurality of bit patterns may correspond to a pulse pattern. The computer-readable medium may be non-transitory.

Additional advantages of the disclosure will be set forth in part in the description which follows, and in part will be obvious from the description, or may be learned by practice of the disclosure. The advantages of the disclosure will be realized and attained by means of the elements and combinations particularly pointed out in the appended claims. It is to be understood that both the foregoing general description and the following detailed description are exemplary and explanatory only and are not restrictive of the disclosure, as claimed.

### BRIEF DESCRIPTION OF THE DRAWINGS

The disclosure can be better understood with the reference to the following drawings and description. The components in the figures are not necessarily to scale, emphasis being placed upon illustrating the principles of the disclosure.

FIG. 1 is a schematic diagram of a pulse generation device according to embodiments.

FIG. 2 is a method of generating a pulse signal according to embodiments.

FIG. 3A and B respectively show an example of a transition-based command protocol and control method to generate pulse pattern(s) according to embodiments.

FIGS. 4A and 4B are front panel perspective view and a case interior view, respectively, of an exemplary pulse generation device in a racked-mount case.

FIG. 5 is a block diagram of a pulsed-EPR spectrometer and associated devices.

FIG. 6 is a diagram of an exemplary computing device.

FIGS. 7A and 7B show three-pulse Electron Spin Echo Envelope Modulation (ESEEM) of the ring-2,3,5,6-²H₄-tyrosine neutral radical in a basic aqueous glass at 177 K. FIG. 7A is a three-pulse ESEEM waveform from single collection. The integrated ESE amplitude is normalized to the constant amplitude of the ESE envelope. Vertical bar length represents 10% of the constant amplitude of the ESE envelope. FIG. 7B is an ESEEM spectrum, obtained by Fourier transformation of the waveform in FIG. 7A. The molecular structure of the radical is shown in the inset.

FIG. 8 is a Hyperfine Sublevel Correlation (HYSCORE) spectrum of the ring-2,3,5,6²H₄-tyrosine neutral radical in a basic aqueous glass at 177 k. The first quadrant of the complex Fourier transform of the 2-D waveform is illustrated. Scale bar portrays relative amplitude.

### DETAILED DESCRIPTION OF THE EMBODIMENTS

The following description, numerous specific details are set forth such as examples of specific components, devices, methods, etc., in order to provide an understanding of embodiments of the disclosure. It will be apparent, however, to one skilled in the art that these specific details need not be employed to practice embodiments of the disclosure. In other instances, well-known materials or methods have not been described in detail in order to avoid unnecessarily obscuring embodiments of the disclosure. While the disclosure is susceptible to various modifications and alternative forms, specific embodiments thereof are shown by way of example in the drawings and will herein be described in detail. It should be understood, however, that there is no intent to limit the disclosure to the particular forms disclosed, but on the contrary, the disclosure is to cover all modifications, equivalents, and alternatives falling within the spirit and scope of the disclosure.

This disclosure generally relates to methods, systems, and computer readable storage media that are configured to controllably generate pulses. The disclosure generally relates to a Field Programmable Gate Array (FPGA)-based design that addresses the deficiencies in other pulse programming technologies. The disclosure can provide a low-cost, high-performance, and reliable solution to the synchronization and control of pulses, for example, of logic pulses required for pulsed-EPR experiments. A pulse generating device according to embodiments can include nanoseconds resolution with fast transitions, low jitter, large number of channels (also referred to as “output channels”), fast and flexible programming capabilities, and long enough pulse durations to satisfy relaxation type experiments. The performance of a pulse generating device, according to embodiments, can be benchmarked for 3-pulse ESEEM, by comparison with data obtained by using a different pulsed-EPR spectrometer, and by comparison with data obtained by using a wide bandwidth, digital delay generator or digital AWG-based pulse programmer, operating on the same spectrometer. See, e.g., Warncke, K., and McCracken, J. 2H electron spin echo envelope modulation spectroscopy of strong, a-hydrogen hyperfine coupling in randomly oriented paramagnetic systems, J. Chem. Phys. 101(3):1832-1841 (1994).

The pulse generating device, according to embodiments, can accelerate data acquisition by greater than 3-fold for 1-D and 2-D measurements. The throughput can be limited by other spectrometer components. The pulse generating device, according to embodiments, can thus obviate the complexity and cost of pulse programmer configurations that are based on parallel commercial digital delay generators. Additionally, the programming and transition times of the methods, systems, and computer readable storage media according to embodiments are generally comparable with those of ASIC devices, at significantly reduced cost and greater flexibility. The methods, systems, and computer readable storage media according to embodiments can also be used to satisfy a wide range of timing requirements, for example, from MHz and GHz, for pulsed experiments in spectroscopy, relaxation and imaging.

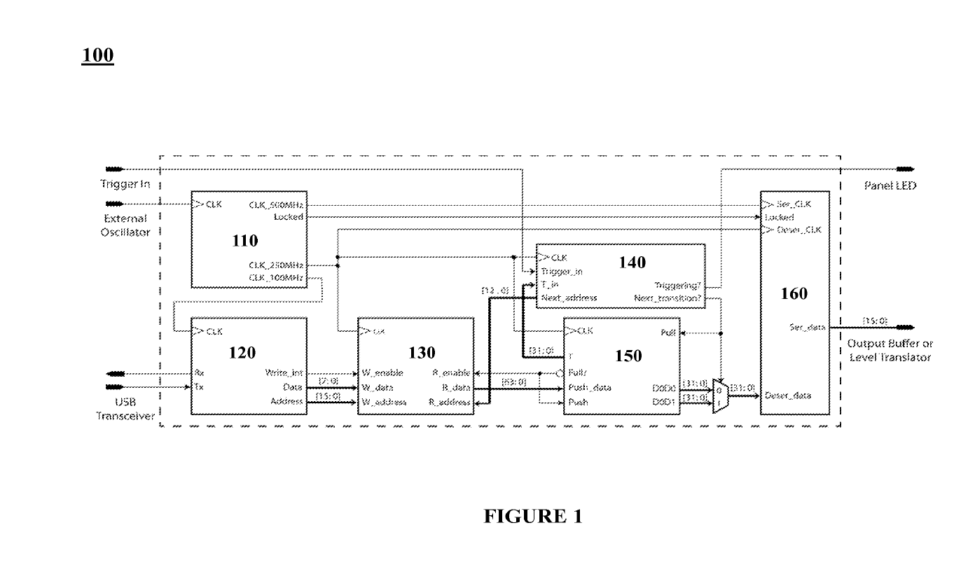

FIG. 1 shows an example of a pulse generating device 100 according to embodiments. As shown in FIG. 1, the pulse generating device 100 may include a digital clock manager 110, a parser 120, at least one memory 130, a pulse control module 140, a command module 150, and an output module 160.

The pulse generating device 100 may generate pulses based on a transition-based command protocol, for example, that can be helpful for magnetic resonance experiments. In general, timing pulses in magnetic resonance experiments can occur infrequently, in comparison with the total pattern length. The protocol can obviate the need for time-consuming pre-calculation and storage of output patterns for each clock cycle, for example, as found for the AWG. FIG. 1 also illustrates how the transition-based command protocol may be processed among the modules of the pulse generating device 100.

In some embodiments, the pulse generating device 100 may be an FPGA-based device. The device may be any FPGA device, for example, including but not limited to a Spartan-6 LX45 (Xilinx). The pulse generating device 100 may include microprocessor(s), at least one memory as well as I/O so as to form a “complete system” on a chip.

In some embodiments, the digital clock manager 110, the memory 130, and the command module 150 may use Xilinx IP cores, for specific hardware functions. In other embodiments, the digital clock manager 110, the memory 130, and the command module 150 may use other cores.

In some embodiments, to maintain a synchronized logic among the memory 130, pulse control module 140 and the command module 150, the main operating frequency may be kept low, for example, at about 250 MHz. A serialization approach can be utilized with the output module 160 to achieve the nanosecond timing resolution, for example, that can be required for pulsed-EPR experiments. In some embodiments, the output module 160 can be configured to function as a serializer, with a wider input width at a lower clock speed and a narrower output width at a higher clock speed. The integral ratio of the input width to the output width, which equals the ratio of the higher clock speed to the lower clock speed, can be denoted as the serialization factor. In some embodiments, a serialization factor of 2 can be used to establish a 2 ns timing resolution. In other embodiments, a different factor can be used. For example, a serialization factor may be 4. In some embodiments, a serialization factor of 4 with an output serialization clock of about 1 GHz can be used and an input de-serialized data width of 64 bits can be used, for example, for about 1 ns resolution on 16 channels (also referred to as “output channels”) with about 250 MHz input clock.

In operation, for example, an on-board, external 100 MHz oscillator signal can be buffered and fed into an on-device phase locked loop (PLL) unit to generate low-jitter (<150 ps) about 500 MHz, 250 MHz, and 100 MHz clock signals. These clock signals can be distributed through global clock lines to allow low-skew and low-delay propagation, in the ISE implementation.

In some embodiments, the digital clock manager 110 may be configured to generate clock signals. The manager 110 may be configured to generate about 500 MHz, 250 MHz, 100 MHZ, among others, as well as any combination therof. The manager 110 may be configured to generate at least three different clock signals. For example, the manager 110 may be configured to generate at least a first clock signal having a first frequency for the parser 120 and memory 130; a second clock signal having a second frequency for the main operation; and a third clock signal for the output module 160. In some embodiments, the first clock signal may correspond to about 100 MHz, the second clock signal may correspond to about 250 MHz, and the third clock signal may correspond to about 500 MHz. The clock speeds may be adjustable according to the user's timing resolution requirements.

In some embodiments, the parser 120 may be configured to receive incoming transmission of user instructions and parses them into operations that write specific bytes into selected memory addresses. The parser 120 may be configured to operate at 100 MHz, as well as any other known frequency.

In some embodiments, the device 100 may include one memory 130. In other embodiments, the device 100 may include more than one memory 130.

In some embodiments, the at least one memory 130 may be a dual port block memory that includes a write port and a read port. In some embodiments, the memory 130 may include an 8-bit write port and a 64-bit read port that is configured to store the transition commands. For example, for 64-bit transition commands, required for the 2 ns, 16 channel configuration, can be organized as follows: the first 32 bits (T_{T}) may be the transition time in the 4 ns (about 250 MHz) time base, the next 16 bits (D₀) may be the output of 16 channels prior to transition, and the last 16 bits (D₁) may be the output at the transition time. With a serialization factor of 2 for the output module 160, the 32-bit input may include D₀D₀ before the transition, and D₀D₁ at the transition time.

In some embodiments, the memory 130 may include a read port width configured up to 256 bits. This can allow a wide range of configurations of transition commands to be used for different timing and channel number requirements. For example, if 1 ns timing resolution and 16 channels are desired, a 128 bit read width can be configured for the memory 130. The first 64 bits (T_{T}) can represent the transition time, and next four 16 bits can represent the data (D₀, D₁, D₂, and D₃), thus accommodating a serialization factor of 4. In this case, the 64-bit input to the output module 160 may include D₀D₀D₀D₀ before the transition, and D₀D₁D₂D₃ at the transition. However, it will be understood that the timing and number of channels may be different. For example, the number of channels may be more or less than 16. In some embodiments, the number may be any number including and between 2-16 channels or more than 16 channels.

In some embodiments, each transition command may include at least one bit pattern. In some embodiments, a plurality of transition commands and/or bit patterns may correspond to a pulse pattern or a waveform pattern. In some embodiments, each bit pattern may correspond to a transition time. In some embodiments, each bit pattern may include: at least one set of bits representing a transition time; at least one set of transition bits including a voltage state for each channel for the transition time; and at least one set of non-transition bits including a voltage state for each channel for a counter value (or time) that is different from the transition time.

In some embodiments, each bit pattern may include one set of non-transition bits. In other embodiments, each bit pattern may include more than one set of non-transition bits. In some embodiments, each bit pattern may include one set of transition bits. In other embodiments, each bit pattern may include more than one set of transition bits. In some embodiments, the number of sets of transition bits may depend or be based on the serialization factor. For example, if the serialization factor is 4, there may be three sets of transition bits and one set of non-transition bits. In this way, the number of sets of non-transition and transition bits may correspond to the serialization factor.

Applying the example above, the at least one set of bits associated with a transition time may correspond to first 32 bits (T_{T}), the at least one set of non-transition bits may correspond to the next 16 bits (D₀); and the at least one set of transition bits may correspond to the last 16 bits (D₁).

In some embodiments, the memory 130 may also store (e.g., an initial) a command associated with the pulse pattern. The command may include a number of transitions (or bit patterns), a pattern end time, an output state of each channel before a trigger occurs, and a location in the memory 130 of the first bit pattern of the plurality of bit patterns associated with the pulse pattern.

In some embodiments, the voltage state may include a first voltage state and a second voltage state. The first voltage state may correspond to “0” and the second voltage state may correspond to “1.” In some embodiments, the first voltage state may be different from the second voltage state. The first voltage state may be associated with a first voltage and the second voltage state may be associated with a second voltage. In some embodiments, the first voltage state may be associated with a voltage lower than the second voltage associated with the second voltage state.

In some embodiments, the first and second voltages associated with the first and second voltage states may be fixed by the output module 160. In some embodiments, the fixed voltages may be adjusted by a user in the output module 160.

The first and second voltages may be any voltages. The first voltage may include but is not limited to a voltage below about 0.8 and the second voltage may include but is not limited to above about 2 volts.

In some embodiments, the read address input of the memory 130 may be registered. In this way, the read data can be configured to lag two clock cycles behind a change on the read address input.

In some embodiments, the pulse control module 140 may be a control logic and Finite State Machine (FSM) module. The pulse control module 140 may be configured to control the buffering by the command module 150.

In some embodiments, the command module 150 may be configured to buffer the memory 130 readout. In some embodiments, the command module 150 may include a buffer. In some embodiments, the command module 150 may include four 64-bit registers. The command module 150 may be configured to access a finite number of sets of transition bits or bit patterns. In some embodiments, the number may include but is not limited to four. In some embodiments, more than four sets of transition bits or bit patterns may be accessed if required.

In some embodiments, the command module 150 may be configured to monitor or track the transition of command usage (e.g., bit pattern usage). If new commands (e.g., bit patterns) are needed, the commands may be transferred from the memory 130 into the module 150 by overwriting used commands (e.g., bit patterns). The control module 140 may be configured to cause a transfer of each bit pattern individually and/or sequentially to the command module 150.

In some embodiments, the command module 150 may access each bit pattern individually and/or sequentially. The accessing or transferring of each bit pattern may be dependent on the bit pattern position and/or transition time. In some embodiments, a bit pattern may include voltage states for each channel according to a cycle of a transition (e.g., from trigger state through transition time).

For example, after the triggering state and/or transition, the pulse control module 140 may cause a new bit pattern to be transferred from the block memory 130 into the command module 150 by overwriting the previously, used bit pattern. In this way, the transition times and voltage states for each channel for the bit patterns may only need to be stored and buffered instead of the full pattern waveform or pulse pattern. This can allow full of advantage of the speed of the device while the amount of data stored in the memory 130 and command module 150 is minimized and thus improve operation.

In some embodiments, the device 100 may be configured to cause a voltage to be outputted from each channel according to the voltage state included the bit pattern based on the counter time of the clock. For example, if the time corresponds to the non-transition time (e.g., time before the transition), the output module 160 may be caused to output, by the control module 140, a voltage according to a set of non-transition bits (e.g., D₀D₀) buffered by the command module 150. For example, if set of non-transition bits includes 0000000000010111 (read binary from right to left) and the output module 160 is configured with 16 channels, the output module 160 may be configured to cause an output of a second voltage from channels 1-3 and 5, and of a first voltage from channels 4 and 6-16. In this example, the first voltage may be a lower voltage than the second voltage. It will be understood that the output module 160 may be configured with more or less channels (e.g., more or less than 16 channels (e.g., any number between 2-16 or more than 16)).

In some embodiments, the device 100 may be connected to an output buffer (not shown). The output buffer may be any external device configured to protect the device and/or boost the current of the outputs (generated pulses). The output buffer may be between the device 100 and another external device. The other external device may include but is not limited to devices configured to perform pulsed experiments (e.g., pulsed-EPR spectroscopy), laser devices, oscilloscopes, medical imaging devices, among others.

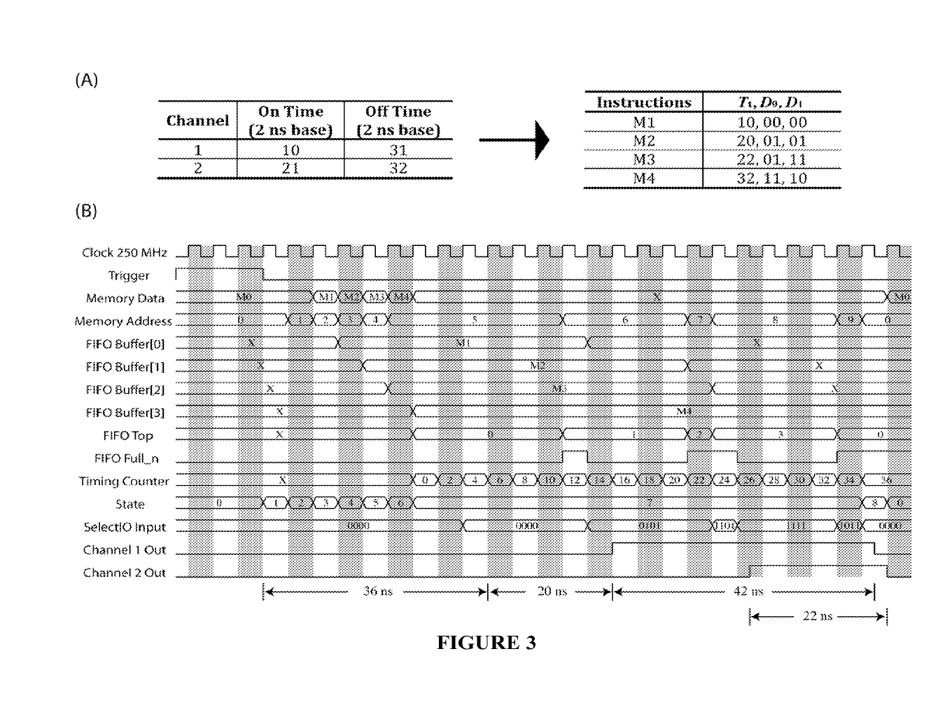

FIG. 3A illustrates an example of a transition-based command protocol (pulse pattern program) and FIG. 3B illustrates how the method can generate a pulse signal according to embodiments. This command protocol example shown in FIG. 3A is based on a serialized 500 MHz time base, with 2 ns time resolution and 2 (output) channels. The function of this example pulse program is to create a pulse on channel 1 from 20 ns to 62 ns, and another pulse on channel 2 from 42 ns to 64 ns. This arrangement could correspond to the gating of the TWT amplifier (channel 1), which has a relatively long rise-time, and the formation of the low power pulse by a PIN diode switch (channel 2). The pulse pattern can translate into 4 memory instructions as listed in FIG. 3B. The pulse control module 140 may be configured to cause the generation of pulses based on a stored control method. When a falling edge on the trigger is detected, the internal state can proceed from state 0 to state 6, and during those states, memory instructions can be buffered into the command module 150 sequentially, as shown in FIG. 3B. After command FIFO is prepared, a timing counter starts, and can be compared with the T_{T} field of the current command in the command module 150. The current command in the command module 150 can be indexed with the “FIFO Top” register. When a transition is reached (at 10 ns, 20 ns, 22 ns, and 32 ns in FIG. 3B), this index can be incremented by one, and the FIFO consumption flag (“FIFO Full_n”) is set, resulting in the next memory instruction (e.g., bit pattern) being pushed into the command module 150 from the memory 130. The method can continue until a pattern end time (stored in M0) is reached.

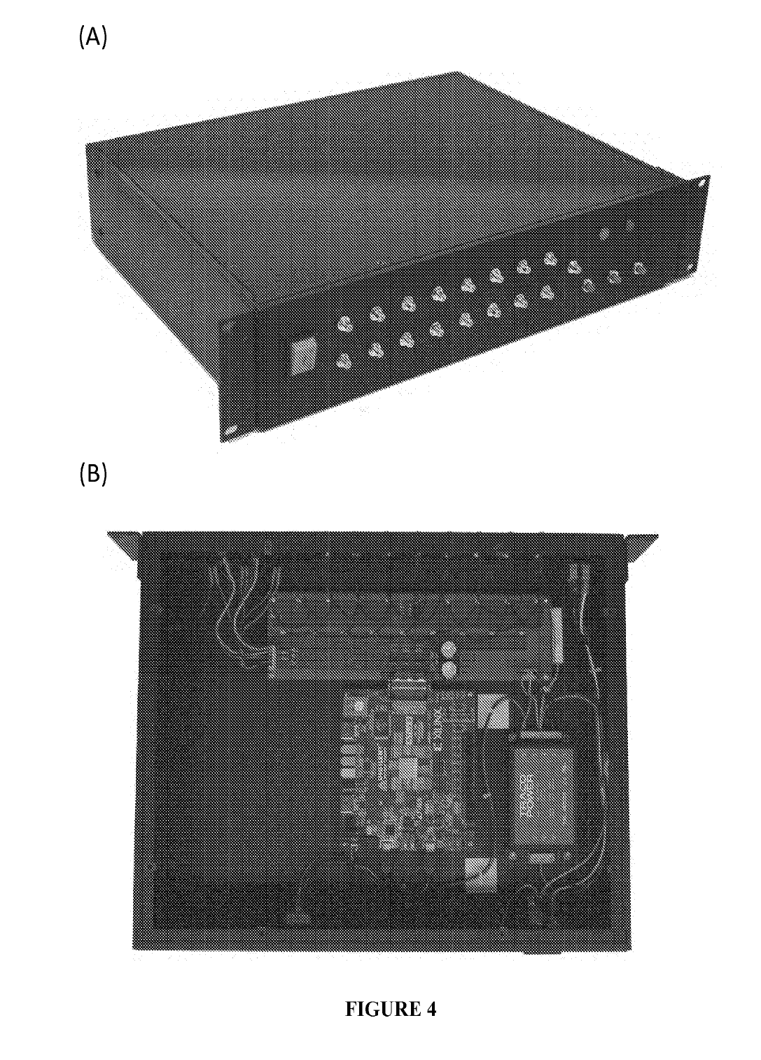

FIGS. 4A and 4B show an example of a pulse generating device according to embodiments. FIG. 4A shows the front panel perspective view and 4B show the case interior view. The pulse generating device may include an Atlys development board (Digilent, Pullman Pa.) employed with the Xilinx Spartan-6 LX45 FPGA. The Atlys platform can provide the serial flash memory device to program and configure the device. Configuration files may be loaded into the device through, for example, an on-board USB transceiver. An auxiliary board may be connected to the Atlys board via a VHDCI connector. In the exemplary implementation, the outputs of timing pulses may be buffered with an IC (OPA693; Texas Instruments, Dallas Tex.), which is an 800 MHz high-speed op-amp that provides a slew-rate of 2,500 V/μs and can supply or sink currents as high as 200 mA to drive high capacitive loads (>100 pF). If higher slew-rate or output current are desired, other opamp buffers, such as the OPA2670 (Texas Instruments, Dallas Tex.), with a slew-rate of 5,000 V/μs and max output current of 700 mA, can be implemented. The timing pulses can be routed 10 through U.FL connectors and WRL-09145 cable (Sparkfun Electronics, Boulder Colo.), into SMA connectors on the front panel, which provide the device-spectrometer interface. The board and the auxiliary board may be powered by a dual-voltage external power supply (TML 40205C, Traco, Zurich, Switzerland), and mounted in a 19″ aluminum rack-mount case. The individual components of the pulse generating device and the layout are shown in FIGS. 4A and 4B.

In some embodiments, the device may be enhanced. The specifications of the pulse generating device, as described, can be enhanced. For example, by utilizing step recovery diodes, the output pulse transition time can be reduced to the order of 50 ps. For example, if the device includes an FPGA integrated circuit (IC), the circuit also has a large number of I/O pins (232, for the Spartan-6 LX45, CSG324 package), and thus, the number of (output) channels can be correspondingly large. In some embodiments, the device may be configured so that outputs could be routed to additional digital delay chips on individual channels, to achieve picosecond timing resolution.

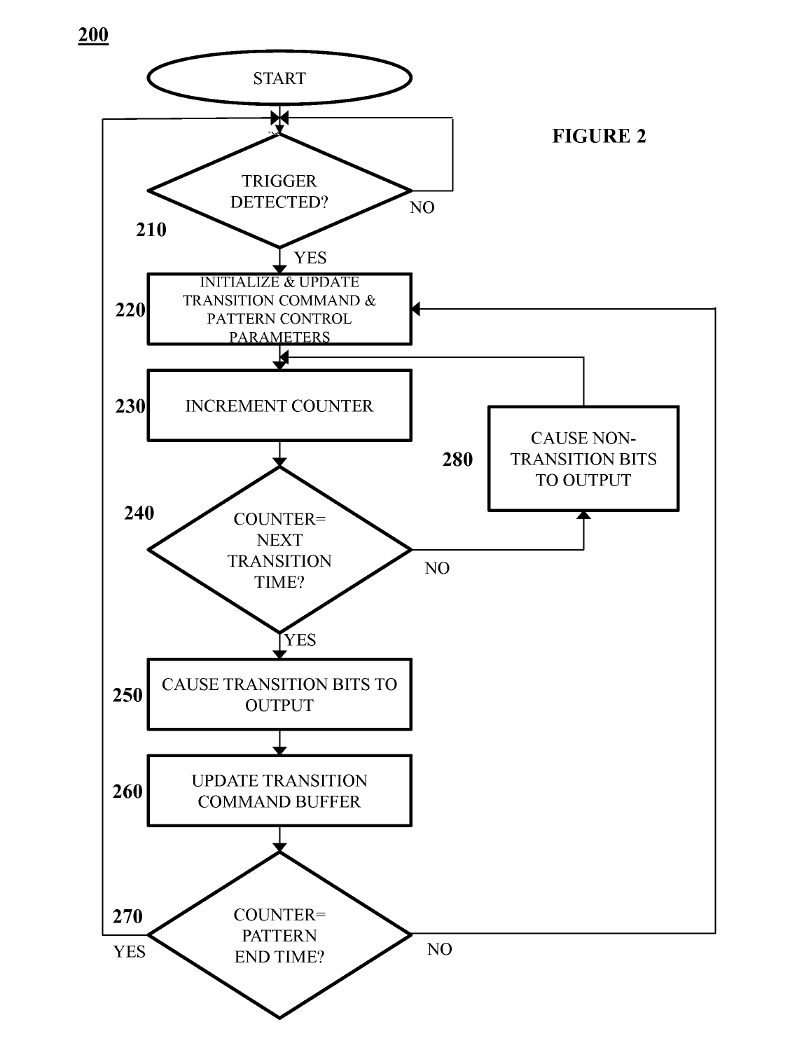

FIG. 2 shows a method 200 of generating and/or causing a pulse to be generated according to embodiments.

The methods of the disclosure are not limited to the steps described herein. The steps may be individually modified or omitted, as well as additional steps may be added.

Unless stated otherwise as apparent from the following discussion, it will be appreciated that terms such as “detecting,” “receiving,” “counting,” “initializing,” “setting,” “updating,” “causing,” “generating,” “determining,” “obtaining,” “processing,” “computing,” “incrementing,” “selecting,” “tracking,” “accessing,” “transferring,” or “monitoring” or the like may refer to the actions and processes of a computer system, or similar electronic computing device, that manipulates and transforms data represented as physical (e.g., electronic) quantities within the computer system's registers and memories into other data similarly represented as physical quantities within the computer system memories or registers or other such information storage, transmission or display devices. Embodiments of the methods described herein may be implemented using computer software. If written in a programming language conforming to a recognized standard, sequences of instructions designed to implement the methods may be compiled for execution on a variety of hardware platforms and for interface to a variety of operating systems. In addition, embodiments are not described with reference to any particular programming language. It will be appreciated that a variety of programming languages may be used to implement embodiments of the disclosure.

In some embodiments, the method 200 may start, for example, when the pulse generating device is turned on and/or connected to another device (e.g., a computer or a device used for the experimentation). It will be understood that the digital clock manager 110 operates continuously in parallel to all of the steps. For example, the digital clock manager 100 may be configured to generate a first clock signal, a second clock signal and a third clock signal. In some embodiments, the first clock signal may correspond to about 100 MHz, the second clock signal may correspond to about 250 MHz, and the third clock signal may correspond to about 500 MHz. The clock speeds may be adjustable according to the user's timing resolution requirements. The digital clock manager 100 may be configured to start generating the clock signals once the device is turned on and may be configured to stop only when the device is turned off.

The method 200 may include a step 210 of detecting a trigger to start generating and/or causing a pulse to be generated. The trigger may be an external trigger signal. The external trigger signal may correspond, for example, to signal sent by an external user interface device. The external trigger may, for example, correspond to pushing a button on a computer or other device or be automatically sent when user instructions are sent to the device. The signal may correspond to a pulse (e.g., a 5 Volt) generated by an external user interface device. The trigger signal may be configured to initiate the processing of the instructions, for example, stored in the memory 130. The instructions may be previously loaded onto the memory 130 through the parser 120.

In some embodiments, the trigger may be detected by the pulse control module 140. When a trigger signal is received, the trigger signal may be routed into one of the pins of the output module 160. The value may then be registered at every main operation cycle (e.g., about 250 MHz) and can be accessed by the pulse control module 140. When the pulse control module 140 determines a transition in the trigger signal, the pulse control module 140 may cause the start of advancement to the “triggering state.”

Next, in step 220, the transition command buffer and the pattern control parameters may be updated. In some embodiments, the pulse control module 140 may store the parameters and the memory 130 may store the values corresponding to the parameters. The parameters may include but is not limited to the total pattern time and the buffer indexes (the FIFO Top, and the FIFO Full_n variables). The buffer indexes may include at least two indexes. The indexes may include a first index (e.g., FIFO Top) configured to cause the station machine's current position in the buffer (e.g., the next position) to be kept tracked and a second index (e.g., FIFO Full_n) to cause the update of the buffer.

In some embodiments, the transition command buffer may be configured to cause a finite number of commands at the main operation clock speed to be buffered or accessed by the command module 150. In some embodiments, the transition command may include at least one bit pattern. In some embodiments, the transition times and voltage states for each channel may only be stored in the bit patterns instead of the full waveform pattern. In this way, operation may be improved because this allows full of advantage of the speed of the device while the amount of data stored in the memory 130 and command module 150 is minimized In this step 220, the other values (e.g., buffer indexes, the total pattern time, and the counter (set to zero)) may be initialized.

Next, the method 200 may include a step 230 of incrementing the time counter. In the triggering state of the pulse control module 140, the time counter will be incremented to one. The time counter may be continue to be incremented by one every main operation clock cycle (250 MHz) until the pattern end time is reached.

Next, the method 200 may include a step 240 of determining whether the counter equals the next transition time. In this step, the counter value may be compared to the next transition time in the command buffer.

If the counter value does not equal the transition time (NO at step 240), the method 200 includes a step 280 of causing a voltage according to the voltage state associated with each channel included in the at least one set of non-transition bits included in the bit pattern to be outputted from each channel, for example, by the output module 160 to another device (e.g., via an output buffer). The set of non-transition bits may be loaded into the output module 160 for output by the pulse control module 140. The set of non-transition bits may include two sets of bits, e.g., because the output module may be configured to act as a duplexed serializer. The set non-transition bits may include any number of sets and the number of sets may depend on the serialization factor. For the set of non-transition bits and a serialization factor of 2, the two bit set may be duplicates of each other as there is no transition in the associated clock cycle (e.g., D₀, D₀). The method 200 may then proceed to step 230.

If the counter value (e.g., time) equals the transition time (YES at step 240), the method 200 includes a step 250 of causing a voltage according to the voltage state associated with each channel included in the at least one set of transition bits included in the bit pattern to be outputted from each channel, for example, by the output module 160 to another device (e.g., via an output buffer). The set of transition bits may be loaded into the output module 160 for output by the pulse control module 140. Like the at least one set of transition bits, the at least one set of transition bits may include any number of sets and the number of sets may depend on the serialization factor. For the set of transition bits and a serialization factor of 2, the two bit set may not be duplicates of each other as there is a transition in the associated clock cycle (e.g., D₀, D₁). Serialization of data allows the device to run at a lower rate (e.g., about 250 Hz) while outputting the data at a higher rate (e.g., about 500 MHz). Although in the examples above discuss a serialization rate of 2, the rate may be changed and can be adjusted, for example, to accommodate higher timing resolutions.

After step 250, the method 200 may include a step 260 of updating the transition command buffer. The step 260 may include updating the bit pattern to another bit pattern. In some embodiments, the command module 150 may be configured to monitor or track transition command usage. If new commands are needed, the pulse control module 140 may cause new commands (e.g., bit pattern(s)) to be transferred from the block memory 130 into the command module 150 by overwriting used commands (e.g., bit pattern(s)). Next, the method may include a step 270 of determining whether the counter equals the pattern end time. The counter value may be compared to the pattern end time. If they are equal (YES at step 270), the pulse control module 140 may be configured to cause the device to be reset to the pre-trigger state (before step 210). If they are not equal (NO at step 270), the method 200 may then proceed to step 220.

In some embodiments, the disclosed methods (e.g., FIG. 2) may be implemented using software applications that are stored in a memory and executed by a processor (e.g., microprocessor) provided on the device. In some embodiments, the disclosed methods may be implanted using software applications that are stored in memories and executed by processors distributed across the device. As such, the modules of the system may be a general purpose computer system that becomes a specific purpose computer system when executing the routine of the disclosure. The modules of the system may also include an operating system and micro instruction code. The various processes and functions described herein may either be part of the micro instruction code or part of the application program or routine (or combination thereof) that is executed via the operating system.

It is to be understood that the embodiments of the disclosure may be implemented in various forms of hardware, software, firmware, special purpose processes, or a combination therof. In one embodiment, the disclosure may be implemented in software as an application program tangible embodied on a computer readable program storage device. The application program may be uploaded to, and executed by, a machine comprising any suitable architecture. The device and method of the present disclosure may be implemented in the form of a software application running on a computer device, for example, a mainframe, personal computer (PC), handheld computer, server, integrated circuit etc. The software application may be stored on a recording media locally accessible by a computing device and accessible via a hard wired or wireless connection to a network, for example, a local area network, or the Internet.

It is to be further understood that, because some of the constituent device components and method steps depicted in the accompanying figures may be implemented in software, the actual connections between the systems components (or the process steps) may differ depending upon the manner in which the disclosure is programmed. Given the teachings of the disclosure provided herein, one of ordinary skill in the related art will be able to contemplate these and similar implementations or configurations of the disclosure.

In some embodiments, the pulse generating device according to embodiments may be used with an external device. For example, the external device may include but is not limited to, medical imaging devices (e.g., nuclear magnetic resonance (NMR), or magnetic resonance imaging (MRI)), spectrometers (e.g., pulsed-EPR spectrometer), laser devices, among others. For example, the pulse generating device according to embodiments may be used to pulse perturbation and detection bandwidths in spectroscopies up through the optical range.

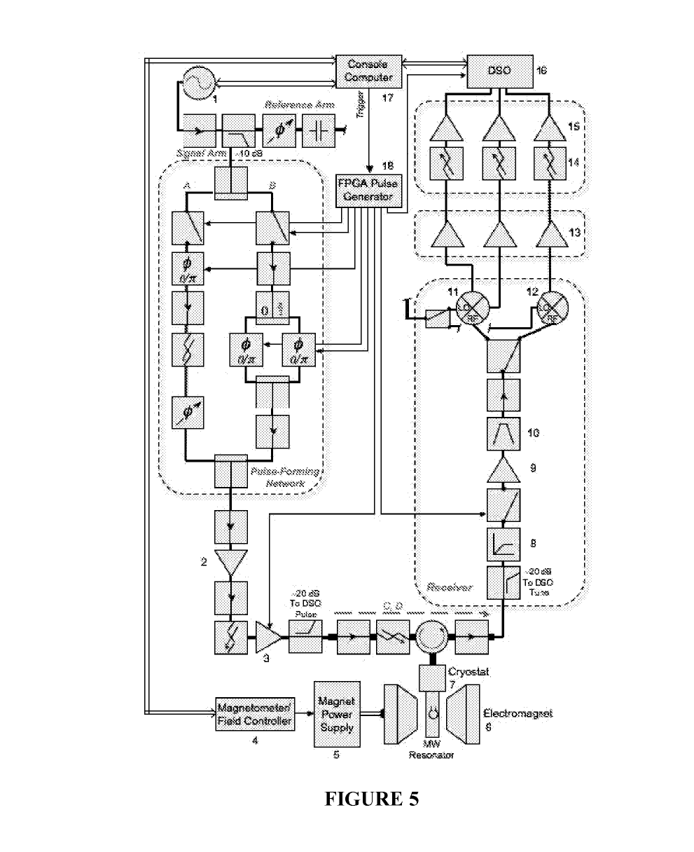

FIG. 5 shows an example of a pulsed-EPR spectrometer configured to be used with a pulse generating device according to some embodiments. However, the pulse generating device may be used with any known pulsed-EPR spectrometer.

As shown in FIG. 5, the spectrometer may include broadband components that allow operation over the full X-band (8.2-12.4 GHz) and Ku-band (12.4-18.0 GHz) MW frequency ranges.

As shown in FIG. 5, the spectrometer may include the following:

(1) a microwave synthesizer/sweeper e.g., (0.01-20 GHz; power: −15 dBm min., 10 dBm max., leveled), 83752A, Hewlett Packard;

(2) an amplifier, e.g., (GaAs FET, 40 dB), ALM/180-5040, CTT;

(3) a travelling wave tube amplifier, e.g., [42 dB, 1 kW max., 1.5% duty cycle, rf output rise/fall 15 ns, phase droop correction option; includes interchangeable output isolator: C1-X153141 (Xband), C1-P153112 (Ku-band)], 117X/Ku, 54303-1, Applied Systems Engineering;

(4) a magnetomer-field controller, e.g., B-H15, Bruker;

(5) a magnet power supply (0-85 A at 0-170 VDC, HS1785-455, Walker Scientific (6) Electromagnet (1.2 T at 85 A, max.), HF-12H, Walker Scientific;

(7) a cryostat, e.g., SVT-200, Janis Research Co.;

(8) a limiter, e.g., (PIN diode; threshold, +9 dBm; response/recovery time, 10-20 ns), LP8018, Herotek;

(9) an amplifier, e.g., (GaAs FET, 21 dB), ALM/180-5021, CTT;

(10) a band pass filter, e.g., (2-18 GHz), 3DH1-2000/T18000-00, K&L Microwave;

(11) a quadrature mixer, e.g., 250270, Anaren Microwave;

(12) a double balanced mixer, e.g., 73230, Anaren Microwave;

(13) an amplifier stage, e.g., encased unit contains the following four amplifiers, on four selectable separate channels: Two bipolar amplifiers (dc-300 MHz; 10×), 6950; two bipolar amplifiers (dc-100 MHz, 100×), 6931; Philips Scientific;

(14, 15) an amplifier stage, e.g., encased unit that contains the following two amplifiers and attenuators, on selectable, separate channels: Amplifier (dc-190 MHz; 20 dB), E220-N-BNC-50-50-25, Comlinear Corporation; Dual rotary attenuator (0-50 dB), 50DR-003, JFW Industries, Inc; (16) Digital sampling oscilloscope, (500 MHz bandwidth, 2.5 GSa/s, 2 active, 2 passive channels, Advanced Math option), TDS620B, Tektronix;

(17) a console computer; and

(18) a pulse generating device according to embodiments (e.g., FIGS. 1 and 4(A) and 4(B)).

The MW circuit in the spectrometer may include capabilities for performing both Electron Spin Echo (ESE) and Fourier transform (FT)-EPR experiments. The continuous-wave output of a broadband MW synthesizer (HP83752A, 0.01-20 GHz; Hewlett-Packard, Palo Alto, Calif.) may be divided into reference and signal channels, for a homodyne detection scheme. The signal channel may enter the pulse-forming network, which may be divided into two arms, as follows: (1) The “A” arm may include a PIN diode switch and biphase modulator, for performance of standard 2- and 3-pulse ESE experiments. A continuously variable phase shifter and a variable attenuator may be present in the ESE arm for manual adjustment of the MW phase and power. This can accommodates phase adjustments between the arms, for experiments that require sophisticated phase cycling schemes, or pulses with different MW power. (2) The “B” arm may include a PIN diode switch, for MW pulse formation, followed by the combination of a 90° hybrid coupler, parallel biphase modulators, and combiner. This block may allow microwave phase alternations of 0, 90, 180 and 270°, for phase-cycling sequences that correct for imbalances of the phases and amplitudes in the two quadrature channels. See, e.g., Hoult, D. I., and Richards, R. E. Critical Factors in the Design of Sensitive High Resolution Nuclear Magnetic Resonance Spectrometers. Proc. R. Soc. Lond. A, 344(1638):311-340 (1975).

The low power MW pulses may pre-amplified by a GaAs FET amplifier (40 dB), ALM/180-5040, CTT, Sunnyvale, Calif.), and then elevated to a power of 1 kW by a pulsed-traveling wave tube (TWT) amplifier (117X/Ku, 54303-1, Applied Systems Engineering, Fort Worth, Tex.). The high power MW pulses may be attenuated, and interact with the sample in a reflection MW resonator arrangement. The high power pulses, and the delayed EPR signal, then enter the receiver.

The receiver components may be configured to be protected from the high power pulses by a PIN diode switch and a limiter. A broadband band-pass filter may attenuate the switch transients. The receiver may include a quadrature mixer and a double-balanced mixer, which are used for different experiments. The intermediate frequency (IF) signal from mixing of the MW signal (RF port) and reference (LO port) arms may be amplified in two stages, attenuated, and then enters the digital sampling oscilloscope (DSO; TDS 620B, Tektronix, Beaverton, Oreg.). Signals can be averaged, stored temporarily, and combined in the DSO, and the data may then be transferred to the operating computer.

The primary microwave resonator design may be the folded stripline, half-wave resonator. See, e.g., Lin, C. P. et al. A Folded Half-Wave Resonator for ESR spectroscopy. J. Magn. Reson. 65:369-374 (1985). These resonators may be held in a Teflon block, which is inserted into a section of WR-90 (Xband) or WR-62 (Ku-band) brass waveguide. An adjustable short may be used to optimize resonator coupling to the waveguide mode. Microwave power may be admitted to the cavity by using a Gordon coupling arrangement, essentially as described by, for example, Britt, R. D., and Klein, M. P. A Versatile Loop-Gap Resonator Probe for Low Temperature Electron Spin-Echo Studies, J. Magn. Reson. 74:535-540 (1987). However, other types of loop-gap and bridged loop gap resonators can also be incorporated. For example, see, Froncisz, W. and Hyde, J. S. The Loop-Gap Resonator: A New Microwave Lumped Circuit ESR Sample Structure, J. Magn. Reson. 47: 515-521 (1982); and Pfenniger, S. et al. Bridged-loop gap resonator for pulsed-EPR experiments, Rev. Sci. Instrum. 59(72): 752-760 (1988). The set of folded stripline resonators, with selected resonant frequencies in the X- and Ku-band ranges, may have operating, coupler adjustable loaded Q values of ˜100. The resonator assembly may afford dead times of ˜100 ns, and sensitivity of ˜1014 spins/Gauss for Cu(II)(H20)6 at X-band.

Variable temperature control can be accomplished by using a SuperVaritemp liquid heliumflow cryostat (Janis Research Co., Wilmington, Mass.), that was custom-designed to accommodate the X- and Ku-band waveguide header-resonator assemblies. The cryostat can allow stable temperature control over the range from 6 K to room temperature, by using different cryogens. External magnetic fields at the sample of up to 1.2 T can be created by an electromagnet (HF12H, Walker Scientific), with Hall-effect magnetic field teslameter/controller (BH15, Bruker, Billerica, Mass.).

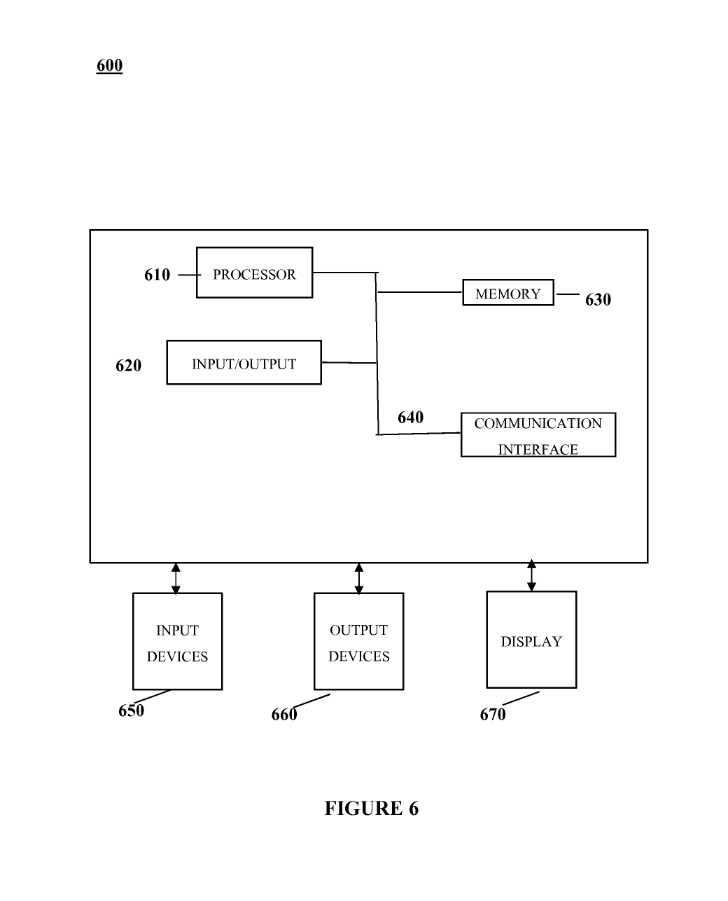

FIG. 6 shows an example of a computer system (also referred to as console computer) 600 that may be used with the pulse generating device. The computer 600 may include any number of modules that communicate with other through electrical or data connections (not shown). In some embodiments, the modules may be connected via a wired network, wireless network, or combination thereof. In some embodiments, the networks may be encrypted. In some embodiments, the wired network may be, but is not limited to, a local area network, such as Ethernet, or wide area network. In some embodiments, the wireless network may be, but is not limited to, any one of a wireless wide area network, a wireless local area network, a Bluetooth network, a radio frequency network, or another similarly functioning wireless network.

Although the modules of the system are shown as being directly connected, the modules may be indirectly connected to one or more of the other modules of the system. In some embodiments, a module may be only directly connected to one or more of the other modules of the system.

It is also to be understood that the system may omit any of the modules illustrated and/or may include additional modules not shown. It is also be understood that more than one module may be part of the system although one of each module is illustrated in the system. It is further to be understood that each of the plurality of modules may be different or may be the same. It is also to be understood that the modules may omit any of the components illustrated and/or may include additional component(s) not shown.

In some embodiments, the modules provided within the system may be time synchronized. In further embodiments, the system may be time synchronized with other systems, such as those systems that may be on the medical facility network.

The system 600 may be a computing system, such as a workstation, computer, or the like. The system 600 may include one or more processors 610. The processor 610 may be one or more of any central processing units, including but not limited to a processor, or a microprocessor. The processor 610 may be coupled directly or indirectly to one or more computer-readable storage medium (e.g., physical memory) 630. The memory elements, such random access memory (RAM), read only memory (ROM), disk drive, tape drive, etc., or a combinations therof. The memory may also include a frame buffer for storing image data arrays. The memory 630 may be encoded or embed with computer-readable instructions, which, when executed by one or more processors 610 cause the system 600 to carry out various functions.

In some embodiments, the system 600 may include a communication interface 640 configured to conduct receiving and transmitting of data between other modules on the system and/or network. The communication interface 640 may be a wired and/or wireless interface, a switched circuit wireless interface, a network of data processing devices, such as LAN, WAN, the interne, or combination therof. The communication interface may be configured to execute various communication protocols, such as Bluetooth, wireless, and Ethernet, in order to establish and maintain communication with at least another module on the medical facility network.

In some embodiments, the system 600 may include an input/output interface 620 configured for receiving information from one or more input devices 650 (e.g., a keyboard, a mouse, and the like) and/or conveying information to one or more output devices 660 (e.g., a printer, a CD writer, a DVD writer, display 670, portable flash memory, etc.). The input/output interface 620 may be further configured to connect to a pulse generating device according to embodiments.

All references cited herein are incorporated by reference in their entirety.

While the disclosure has been described in detail with reference to exemplary embodiments, those skilled in the art will appreciate that various modifications and substitutions may be made thereto without departing from the spirit and scope of the disclosure as series forth in the appended claims. For example, elements and/or features of different exemplary embodiments may be combined with each other and/or substituted for each other within the scope of this disclosure and appended claims.

### EXAMPLE

### Sample Preparation

The ring-2,3,5,6-²H₄-L-tyrosine was obtained from Cambridge Isotope Laboratories (Cambridge, Mass.) and used without further purification. A 20 mM solution of ring-2,3,5,6-²H₄-L-tyrosine in 40% w/v NaOH was placed in a 4 mm outer diameter quartz EPR tube (Wilmad-LabGlass, Buena, N.J.). The sample was then degassed (3 freeze-pump-thaw cycles, with argon gas backfill), and frozen in liquid nitrogen. The sample was irradiated with a 650 W mercury arc lamp UV for 90 s, to induce tyrosine radical formation. See, e.g., Warncke, K., and McCracken, J. 2H electron spin echo envelope modulation spectroscopy of strong, a-hydrogen hyperfine coupling in randomly oriented paramagnetic systems, J. Chem. Phys. 101(3):1832-1841 (1994).

### Pulsed-EPR Spectroscopy

All pulsed-EPR experiments were performed at 170 K, at a MW frequency of 8.3335 GHz, a magnetic field of 297.6 mT, microwave pulse power of 90 W, T value of 256 ns, and initial T value (T₀) of −106 ns, using an pulsed-EPR spectrometer as shown in FIG. 5 and the pulse generating device shown in FIGS. 4A and 4B . The 3-pulse ESEEM sequence, P₉₀-τ-P₉₀T-P₉₀-τ-ESE, with MW pulse-swapping was used, where P is the MW pulse and • is rotation angle, in degrees. The value of P₉₀=20 ns, and a 4-phase cycle sequence was used. See, for example, Fauth, J.-M et al. Elimination of unwanted echoes and reduction of dead time in three-pulse electron spin echo spectroscopy. J. Magn. Reson. 66:74-85 (1986); and Gemperle, C. et al. Phase Cycling in Pulse EPR, J. Magn. Reson. 88:241-256 (1990). Dead-time reconstruction and Fourier transformation of the 3-pulse ESEEM waveform were performed by using the OPTESIM ESEEM simulation and analysis software suite. See, for example, Sun, L et al. OPTESIM, a Versatile Toolbox for Numerical Simulation of Electron Spin Echo Envelope Modulation (ESEEM) that Features Hybrid Optimization and Statistical Assessment of Parameters, J. Magn. Reson. 200(1): 21-28 (2009). The HYSCORE pulse sequence, P₉₀-t-P₉₀-t₁-P₁₈₀-t2-P₉₀-t-ESE, was used, with P₉₀=20 ns, P₁₈₀=40 ns, and 4-phase cycling. See, for example, Stoll, S., and Kasumaj, B. Phase Cycling in Electron Spin Echo Envelope Modulation, Appl. Magn. Reson. 35:15-32 (2008). Acquisition parameters were as specified above, with initial values for t₁ and t₂ of 80 ns. HYSCORE waveforms were baseline corrected in both dimensions.

### Results and Discussion

The FPGA pulse programmer was used to conduct two standard pulsed-EPR experiments, 3-pulse ESEEM and 4-pulse HYSCORE, by using the home-built pulsed-EPR spectrometer. See, for example, Schweiger, A., and Jeschke, G. Principles of pulse electron paramagnetic resonance, Oxford University Press, Oxford, UK, (2001); and Höfer, P et al. Hyperfine Sublevel Correlation (HYSCORE) Spectroscopy: A 2D ESR Investigation of the Squaric Acid Radical. Chem. Phys. Lett. 132(3):279-283 (1986). In the simple 3-pulse ESEEM experiment, the value of τ is fixed, the “waiting time” interval between the second and third pulses, T, is varied, and a 2-phase cycle sequence can be applied. See, for example, Angerhofer, A., Massoth, R. J., and Bowman, M. K. (1988) Fourier-transform EPR measurement of homogeneous electron transfer rates. Israel J. Chem. 28: 227-238 (1988). A variation of the experiment, which is used here, employs values of T<0 to reduce the effective dead time, and requires a 4-phase cycle sequence. See, for example, Fauth, J.-M et al. Elimination of unwanted echoes and reduction of dead time in three-pulse electron spin echo spectroscopy. J. Magn. Reson. 66:74-85 (1986). Ten logic pulses on 7 channels were required for the MW switches, biphase modulators, TWT amplifier, receiver protection switch, and DSO detection gating. The experiment proceeded by collecting integrated 3-pulse ESE amplitude at each pulse-time point, sequentially. The delayed time base of the DSO is incremented to maintain a constant position of the 3-pulse ESE, for screen presentation and integration measurement.

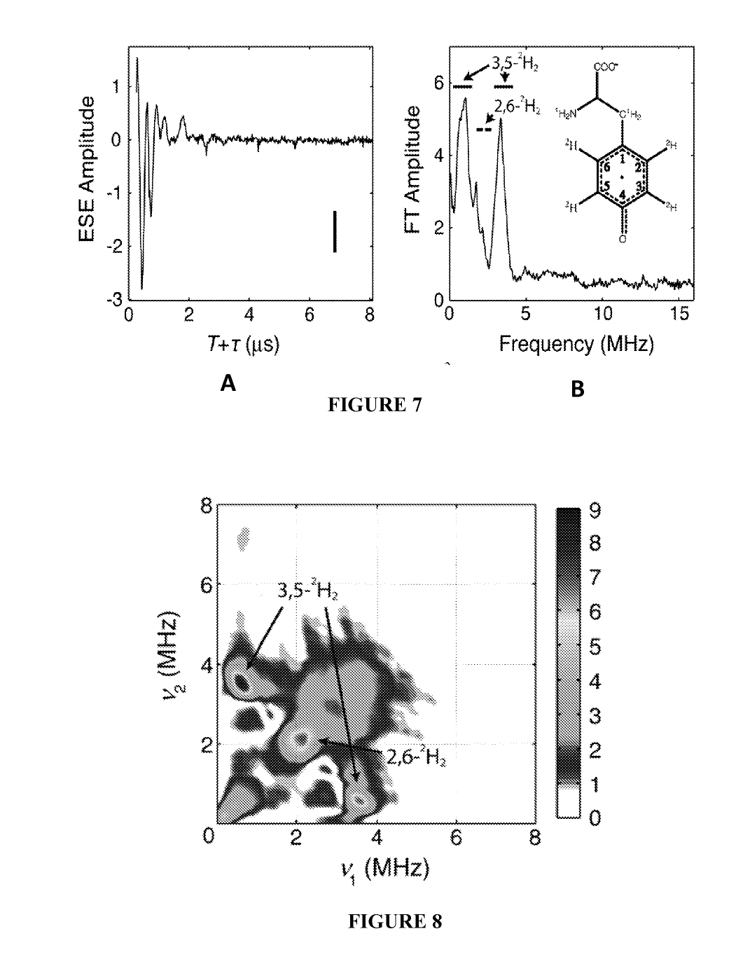

FIGS. 7A and B show the 3-pulse ESEEM waveform and corresponding cosine Fourier transform for the ring-2,3,5,6-²H-(L)-tyrosine radical in 40% w/v aqueous NaOH glass at a temperature of 177 k. FIG. 7A shows a single collected waveform of 400 points. The data acquisition parameters included 32 pulse sequence repetitions per phase per time point (128, total), at a repetition rate of 100 Hz (the maximum possible repetition rate is 14 kHz, which corresponds to a 36 ns trigger delay and the pulse sequence duration), which leads to a dwell time at each data point of 1.28 s. The FPGA programming time is 50 ms. Communications between the console computer and the DSO over the GPIB interface require 0.9 s.

The modulation in the waveform in FIG. 7A is dominated by contributions from the 3,5-²H hyperfine coupling with the unpaired electron spin, which is delocalized over the phenol side chain of tyrosine. The Fourier transform in FIG. 7B shows the two broad hyperfine features from the 3,5-²H coupling, that are centered around the free ²H Larmor frequency of 2.1 MHz. The electron spin density at the ring-carbon 2- or 6-positions is equivalent (ρ_{π}=−0.06), and is less than the equivalent electron spin density at the 3- and 5-positions (ρ_{π}=−0.25). See, e.g., Warncke, K., and McCracken, J. 2H electron spin echo envelope modulation spectroscopy of strong, a-hydrogen hyperfine coupling in randomly oriented paramagnetic systems, J. Chem. Phys. 101(3):1832-1841 (1994); and Warncke, K. et al., Structure of the YD tyrosine Radical in Photosystem II as Revealed by 2H Electron Spin Echo Envelope Modulation (ESEEM) Spectroscopic Analysis of Hydrogen Hyperfine Couplings, J. Am. Chem. Soc. 116(16): 7332-7340 (1994). This leads to the narrow lines and reduced splitting about the ²H Larmor frequency of the 2,6-²H features, as shown in FIG. 7B. The ESEEM waveform and Fourier transform in FIGS. 7A and 7B are comparable to the 3-pulse ESEEM results reported earlier for the 3,5-²H labeled tyrosine radical, and to results obtained on the pulsed-EPR spectrometer, but by using the Tektronix HFS9003 pulse programming. See, e.g., Warncke, K., and McCracken, J. 2H electron spin echo envelope modulation spectroscopy of strong, a-hydrogen hyperfine coupling in randomly oriented paramagnetic systems, J. Chem. Phys. 101(3):1832-1841 (1994). This verifies the performance of the FPGA-based pulse programmer.

HYSCORE is a 2-D experiment, and therefore involves a significant increase in acquisition time, relative to 1-D experiments (the number of points increases from n for 1-D to n² for 2-D). See, for example, Schweiger, A., and Jeschke, G. Principles of pulse electron paramagnetic resonance, Oxford University Press, Oxford, UK, (2001). Two time intervals, t₁ and t₂, are varied, and either 4- or 8-phase cycle sequences are required to remove unwanted coherences. Twelve logic pulses on 7 channels were required for the MW pulse formation, the 4-phase cycling sequence, and gating of the TWT amplification, receiver protection, and detection events. The experiment proceeded by collecting the 4-pulse ESE amplitude at each pulse-time point, sequentially. The 2D waveform was constructed by fixing a t₂ value, and varying t₁, and then incrementing to the next t₂ value, and again varying t₁. The increment was 80 ns, and 128 iterations were performed for each dimension (16,384 iterations, total).

FIG. 8 shows the HYSCORE spectrum for the 2,3,5,6-²H-(L)-tyrosine radical in 40% w/v aqueous NaOH glass at 6 K. The time-domain data acquisition parameters included 32 pulse sequence repetitions per phase per time point (128, total), at a repetition rate of 100 Hz. The dwell time at each point is 1.28 s, which, including the 0.9 s per point for console computer-DSO communications, leads to a total acquisition time of 10 h. This represents a 3-fold decrease in 2D waveform acquisition time, relative to the previous HFS9003-based system, for which the run-time and associated liquid helium cost were prohibitive. The acquisition time would be reduced to 6 h, without the DSO communication bottleneck. The diagonal of the 2-D Fourier transform in FIG. 8 shows the two broad hyperfine features from the 3,5-²H coupling, and the narrower features from the 2,6-²H coupling, around the free ²H Larmor frequency of 2.1 MHz.

What is claimed is:

1. A device configured to generate a pulse, comprising:
a memory storing a plurality of bit patterns, each bit pattern associated with a transition time, each bit pattern including at least one set of bits representing a transition time, at least one set of transition bits including a voltage state for each channel for a counter value that corresponds to the transition time, and a set of non-transition bits including a voltage state for each channel for a counter value that is different from the transition time; and
a processor configured to cause an output of a voltage from each channel corresponding to a voltage state for each respective channel provided in the set of non-transition bits when a counter value is different from the transition time; and a voltage from each channel corresponding to a voltage state for each respective channel provided in the set of transition bits when a counter value is the transition time.

2. The device according to claim 1, further comprising:
an output module configured to output a voltage, the output module having a serialization factor and the output module configured to fix a voltage corresponding to a voltage state.

3. The device according to claim 1, wherein the number of sets of non-transition and transition bits corresponds to the serialization factor.

4. The device according to any of claim 1 wherein the set of non-transition bits and the set of transition bits include a first voltage state and a second voltage state.

5. The device according to claim 4, wherein the first voltage state is lower than the second voltage state.

6. The device according to claim 1,
wherein the processor is further configured to access each bit pattern individually,
wherein the command module is configured to access each bit pattern based on at least one of a transition time or a position of a bit pattern in the memory.

7. The device according to claim 6, wherein the command module is configured to access a number of bit patterns.

8. The device according to claim 1, wherein the processor is further
configured to generate clock signals.

9. The device according to claim 8, wherein the processor is configured to generate at least a first clock, a second clock and a third clock, the second clock corresponding to a main operation clock and the third clock corresponding to an output clock.

10. The device according to claim 8, wherein the second clock is at 250 MHz and the third clock is at 500 MHz.

11. The device according to claim 1, wherein
the processor is further configured to access each bit pattern individually
based on at least one of a transition time or a position of individual bit pattern in the memory.

12. A method to generate a pulse, comprising:
monitoring a counter value;
storing a plurality of bit patterns, each bit pattern associated with a transition time, each bit pattern including at least one set of bits representing a transition time, at least one set of transition bits including a voltage state for each channel for a counter value that corresponds to the transition time, and a set of non-transition bits including a voltage state for each channel for a counter value that is different from the transition time;
causing an output of a voltage from each channel corresponding to a voltage state for each respective channel provided in the set of non-transition bits when a counter value is different from the transition time; and
causing an output of a voltage from each channel corresponding to a voltage state for each respective channel provided in the set of transition bits when a counter value is the transition time.

13. The method according to claim 12, further comprising:
outputting the voltage from each channel according to the voltage state to an external device.

14. The method according to claim 13, wherein the number of sets of transition bits and non-transition bits corresponds to a serialization factor.

15. The method according to claim 14, wherein the set of non-transition bits and the set of transition bits include a first voltage state and a second voltage state.

16. The method according to claim 15, wherein the first voltage state is lower than the second voltage state.

17. The method according to claim 12, further comprising:
accessing each bit pattern individually,
wherein the accessing each bit pattern is based on at least one of a transition time or a position of individual bit pattern in the memory.

18. The method according to claim 12, further comprising:
detecting the trigger; and
generating clock signals.

19. The method according to claim 18, further comprising:
generating at least a first clock, a second clock and a third clock, the second clock corresponding to a main operation clock and the third clock corresponding to an output clock.

20. The method according to claim 19, wherein the second clock corresponds to about 250 MHz and the third clock corresponds to about 500 MHz.
